(19) United States
(12) Patent Application Publication
(10) Pub. No.: US 2024/0351161 A1
(43) Pub. Date: Oct. 24, 2024

(54) POLISHING METHOD AND POLISHING APPARATUS

(71) Applicant: EBARA CORPORATION, Tokyo (JP)

(72) Inventors: Tomoko OWADA, Tokyo (JP); Osamu NABEYA, Tokyo (JP)

(21) Appl. No.: 18/634,631

(22) Filed: Apr. 12, 2024

(30) Foreign Application Priority Data
Apr. 20, 2023 (JP) 2023-069100

(51) Int. Cl. B24B 37/10; B24B 37/005; B24B 57/02

(52) U.S. Cl. CPC B24B 37/10; B24B 37/005; B24B 57/02

(57) ABSTRACT

A polishing method and a polishing apparatus that can suppress fluid from remaining on an upper surface of a workpiece, and that can apply an appropriate force to the workpiece to polish the workpiece are disclosed. The polishing method includes: pressurizing a first pressure chamber to move fluid present between an upper surface of the workpiece and the first pressure chamber outward; moving the fluid present between the upper surface of the workpiece and a second pressure chamber outward by pressurizing the second pressure chamber to form a second pressure in the second pressure chamber which is lower than a target pressure when a pressure equal to or higher than the target pressure is formed in the first pressure chamber; and polishing the workpiece after causing the fluid to flow out from the workpiece.

### CROSS REFERENCE TO RELATED APPLICATION

This document claims priority to Japanese Patent Application No. 2023-069100 filed Apr. 20, 2023, the entire contents of which are hereby incorporated by reference.

### BACKGROUND

Chemical mechanical polishing (CMP) is a technique of polishing a surface of a workpiece by pressing the workpiece against a polishing surface while supplying a polishing liquid onto the polishing surface to place the workpiece in sliding contact with the polishing surface in the presence of the polishing liquid. During polishing of the workpiece, the workpiece is pressed against the polishing surface by a polishing head. The surface of the workpiece is planarized by a chemical action of the polishing liquid and mechanical action(s) of abrasive grains contained in the polishing liquid and/or a polishing pad.

FIG. 22 is a cross-sectional view schematically showing a polishing head 100. The polishing head 100 has an elastic membrane 110 being contacts with an upper surface of a wafer W1, which is an example of the workpiece. This elastic membrane 110 has a shape that forms a plurality of pressure chambers 101 to 104. Pressures in the pressure chambers 101 to 104 can be regulated independently. Therefore, the polishing head 100 can press a plurality of regions of the wafer W1 corresponding to these pressure chambers 101 to 104 with different forces, and can achieve a desired film-thickness profile of the wafer W1.

After polishing of the wafer W1 is terminated, the polished wafer W1 is transferred to a next process by a transfer device. As shown in FIG. 23, a next wafer W2 is moved to a transfer position below the polishing head 100 by the transfer device. At the same time, the polishing head 100 is cleaned with liquid (e.g., pure water) supplied from a cleaning nozzle 115, so that a polishing liquid and polishing debris are removed from the polishing head 100. The next wafer W2 is then held by the polishing head 100 and is transferred to a position above a polishing surface by the polishing head 100. The wafer W2 is pressed against the polishing surface by the polishing head 100 and polished in the presence of the polishing liquid.

However, as shown in FIG. 24, fluid Q, such as the liquid having been used for cleaning of the polishing head 100, or air, may be present between an upper surface of the wafer W2 and the elastic membrane 110 of the polishing head 100. The presence of the fluid Q between the upper surface of the wafer W2 and the polishing head 100 may prevent the polishing head 100 from appropriately applying the forces to the plurality of regions of the wafer W2 corresponding to the pressure chambers 101 to 104. For example, if the fluid Q spreads over some pressure chambers, a pressure in an adjacent pressure chamber is transmitted to the fluid Q, and as a result, an unintended force may be applied to the wafer W2.

Thus, there is a technique of causing the fluid Q to flow out from the wafer W2 by sequentially pressurizing the pressure chambers 101 to 104 from a center side toward an outer side before polishing of the wafer W2. According to this technique, the polishing head 100 is expected to be able to appropriately apply the forces to the wafer W2.

However, as shown in FIGS. 25 and 26, when the inner pressure chamber 101 is pressurized and then the outer pressure chamber 102 is pressurized, the inflation of the elastic membrane 110 between the pressure chamber 101 and the pressure chamber 102 is unbalanced, so that a bottom of the elastic membrane 110 is pulled toward the pressure chamber 102. As a result, the pressure applied to the bottom of the elastic membrane 110 forming the pressure chamber 101 is lowered, so that the fluid Q may flow backward toward the pressure chamber 101.

### SUMMARY OF THE INVENTION

There are provided a polishing method and a polishing apparatus that can suppress fluid from remaining on an upper surface of a workpiece, and that can apply an appropriate force to the workpiece to polish the workpiece.

Embodiments, which will be described below, relate to a technique of causing fluid to flow out from an upper surface of a workpiece, such as a wafer, and polishing the workpiece.

In an embodiment, there is provided a polishing method for a workpiece using a polishing head having a plurality of pressure chambers formed by an elastic membrane, comprising: pressurizing a first pressure chamber to move fluid present between an upper surface of the workpiece and the first pressure chamber outward, the plurality of pressure chambers including the first pressure chamber; moving the fluid present between the upper surface of the workpiece and a second pressure chamber outward by pressurizing the second pressure chamber to form a second pressure in the second pressure chamber when a first pressure is formed in the first pressure chamber, the first pressure being equal to or higher than a first target pressure, the second pressure being lower than the first target pressure, the plurality of pressure chambers including the second pressure chamber located outwardly of the first pressure chamber; and pressing a lower surface of the workpiece against a polishing surface with the elastic membrane to polish the lower surface of the workpiece after causing the fluid to flow out from the upper surface of the workpiece.

In an embodiment, pressurizing the first pressure chamber comprises pressurizing the first pressure chamber to form a first initial pressure in the first pressure chamber which is lower than the first target pressure, and pressure in the first pressure chamber is increased from the first initial pressure to the first target pressure after the first initial pressure is formed in the first pressure chamber.

In an embodiment, the operation of increasing the pressure in the first pressure chamber from the first initial pressure to the first target pressure is started at the same time as or before the pressurization of the second pressure chamber is started.

In an embodiment, pressurizing the first pressure chamber comprises pressurizing the first pressure chamber to form the first target pressure in the first pressure chamber, and pressurizing the second pressure chamber to form the second pressure in the second pressure chamber which is lower than the first target pressure comprises pressurizing the second pressure chamber to form a second target pressure in the second pressure chamber when the first pressure equal to or higher than the first target pressure is formed in the first pressure chamber, the second target pressure being lower than the first target pressure.

In an embodiment, the plurality of pressure chambers further include a third pressure chamber located outwardly of the second pressure chamber, the second pressure in the second pressure chamber which is lower than the first target pressure comprises a second initial pressure lower than the first target pressure, and the polishing method further comprises: lowering pressure in the first pressure chamber from the first target pressure while increasing pressure in the second pressure chamber from the second initial pressure to a second target pressure; and moving the fluid present between the upper surface of the workpiece and the third pressure chamber outward by pressurizing the third pressure chamber to form a third pressure in the third pressure chamber when the second target pressure is formed in the second pressure chamber, the third pressure being lower than the second target pressure.

In an embodiment, there is provided a polishing apparatus for a workpiece, comprising: a polishing table configured to support a polishing pad having a polishing surface; a polishing head having a plurality of pressure chambers formed by an elastic membrane, the polishing head being configured to press the workpiece against the polishing surface with the elastic membrane; and a pressure controlling system configured to control pressures in the plurality of pressure chambers, wherein the plurality of pressure chambers include a first pressure chamber, and a second pressure chamber located outwardly of the first pressure chamber, the pressure controlling system is configured to: pressurize the first pressure chamber to move fluid present between an upper surface of the workpiece and the first pressure chamber outward; move the fluid present between the upper surface of the workpiece and the second pressure chamber outward by pressurizing the second pressure chamber to form a second pressure in the second pressure chamber when a first pressure is formed in the first pressure chamber, the first pressure being equal to or higher than a first target pressure, the second pressure being lower than the first target pressure; and pressurize the plurality of pressure chambers to press a lower surface of the workpiece against the polishing surface with the elastic membrane to polish the lower surface of the workpiece after the fluid is caused to flow out from the upper surface of the workpiece.

In an embodiment, the pressure controlling system is configured to: pressurize the first pressure chamber to form a first initial pressure in the first pressure chamber which is lower than the first target pressure; and increase pressure in the first pressure chamber from the first initial pressure to the first target pressure.

In an embodiment, the pressure controlling system is configured to start the operation of increasing the pressure in the first pressure chamber from the first initial pressure to the first target pressure at the same time as or before the pressurization of the second pressure chamber is started.

In an embodiment, the pressure controlling system is configured to: pressurize the first pressure chamber to form the first target pressure in the first pressure chamber; and pressurize the second pressure chamber to form a second target pressure in the second pressure chamber when the first pressure equal to or higher than the first target pressure is formed in the first pressure chamber, the second target pressure being lower than the first target pressure.

In an embodiment, the plurality of pressure chambers further include a third pressure chamber located outwardly of the second pressure chamber, the second pressure in the second pressure chamber which is lower than the first target pressure comprises a second initial pressure lower than the first target pressure, and the pressure controlling system is configured to: lower pressure in the first pressure chamber from the first target pressure while increasing pressure in the second pressure chamber from the second initial pressure to a second target pressure; and move the fluid present between the upper surface of the workpiece and the third pressure chamber outward by pressurizing the third pressure chamber to form a third pressure in the third pressure chamber when the second target pressure is formed in the second pressure chamber, the third pressure being lower than the second target pressure.

According to the above-described embodiments, the polishing method and the polishing apparatus that can suppress the fluid from remaining on the upper surface of the workpiece, and that can apply an appropriate force to the workpiece to polish the workpiece can be provided.

### BRIEF DESCRIPTION OF THE DRAWINGS

FIG. 1 is a schematic diagram showing an embodiment of a polishing apparatus;

FIG. 2 is a cross-sectional view showing an embodiment of a polishing head;

FIG. 3 is a plan view of a transfer device configured to transfer a wafer to the polishing head shown in FIG. 1;

FIG. 4 is a schematic diagram illustrating fluid present on an upper surface of the wafer;

FIG. 5 is a schematic diagram illustrating an embodiment in which an elastic membrane of the polishing head moves the fluid on the wafer outward;

FIG. 6 is a schematic diagram illustrating an embodiment in which the elastic membrane of the polishing head further moves the fluid on the wafer outward;

FIG. 7 is a schematic diagram illustrating an embodiment in which the elastic membrane of the polishing head further moves the fluid on the wafer outward;

FIG. 8 is a schematic diagram illustrating an embodiment in which the elastic membrane of the polishing head forces the fluid to flow out from the wafer;

FIG. 9 is a graph showing an embodiment of a relationship between pressure in a plurality of pressure chambers and time;

FIGS. 10A to 10C are graphs each showing an example in which the pressures in the pressure chambers change;

FIG. 11 is a schematic diagram illustrating an embodiment in which the elastic membrane of the polishing head moves the fluid on the wafer outward;

FIG. 12 is a schematic diagram illustrating an embodiment in which the elastic membrane of the polishing head further moves the fluid on the wafer outward;

FIG. 13 is a schematic diagram illustrating an embodiment in which the elastic membrane of the polishing head further moves the fluid on the wafer outward;

FIG. 14 is a schematic diagram illustrating an embodiment in which the elastic membrane of the polishing head forces the fluid to flow out from the wafer;

FIG. 15 is a graph showing an embodiment of a relationship between pressure in the pressure chambers and time;

FIG. 16 is a schematic diagram illustrating an embodiment in which the elastic membrane of the polishing head moves the fluid on the wafer outward;

FIG. 17 is a schematic diagram illustrating an embodiment in which the elastic membrane of the polishing head further moves the fluid on the wafer outward;

FIG. 18 is a schematic diagram illustrating an embodiment in which the elastic membrane of the polishing head further moves the fluid on the wafer outward;

FIG. 19 is a schematic diagram illustrating an embodiment in which the elastic membrane of the polishing head forces the fluid to flow out from the wafer;

FIG. 20 is a schematic diagram illustrating an embodiment of a change in pressure in the pressure chambers formed by the elastic membrane of the polishing head;

FIG. 21 is a graph showing an embodiment of a relationship between pressure in the pressure chambers and time;

FIG. 22 is a cross-sectional view schematically showing a polishing head;

FIG. 23 is a diagram illustrating the polishing head being cleaned;

FIG. 24 is a diagram illustrating a problem caused by fluid present between an upper surface of a wafer and an elastic membrane of the polishing head;

FIG. 25 is a diagram illustrating an example in which the fluid present on the upper surface of the wafer flows backward; and

FIG. 26 is a diagram illustrating an example in which the fluid present on the upper surface of the wafer flows backward.

### DESCRIPTION OF EMBODIMENTS

Embodiments will now be described with reference to the drawings.

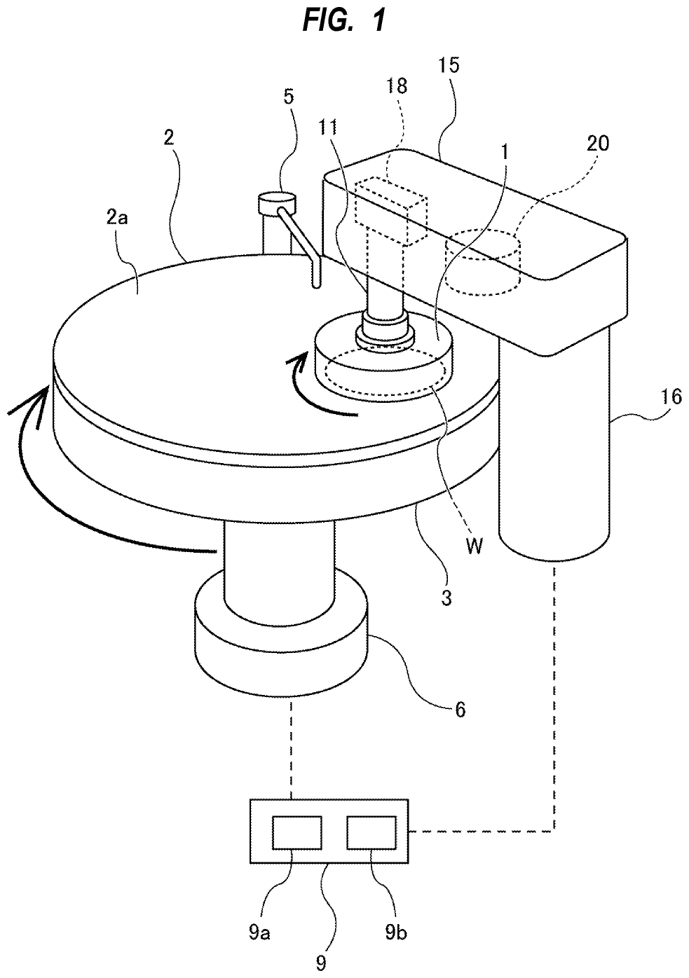

FIG. 1 is a schematic diagram showing an embodiment of a polishing apparatus. As shown in FIG. 1, the polishing apparatus includes a polishing table 3 configured to support a polishing pad 2, a polishing head 1 configured to press a wafer W, which is an example of a workpiece, against the polishing pad 2, a table motor 6 configured to rotate the polishing table 3, and a polishing-liquid supply nozzle 5 configured to supply a polishing liquid (e.g., slurry containing abrasive grains) onto the polishing pad 2. The polishing pad 2 has a surface constituting a polishing surface 2a for polishing the wafer W. Specific examples of the workpiece include a wafer, an interconnect substrate, a quadrangular substrate, etc., for use in manufacturing of semiconductor devices.

The polishing table 3 is coupled to the table motor 6, and is configured to rotate the polishing table 3 and the polishing pad 2 together. The polishing head 1 is fixed to an end of a polishing-head shaft 11, and the polishing-head shaft 11 is rotatably supported by a head arm 15. The head arm 15 is rotatably supported by a support shaft 16.

The polishing-head shaft 11 is coupled to a vertically moving mechanism 18 disposed in the head arm 15. The vertically moving mechanism 18 is configured to vertically move the polishing-head shaft 11 in its axial direction. The vertical movement of the polishing-head shaft 11 caused by the vertically moving mechanism 18 allows the wafer W held by the polishing head 1 to move close to and away from the polishing pad 2 on the polishing table 3. The configuration of the vertically moving mechanism 18 is not particularly limited. In one example, the vertically moving mechanism 18 includes a servo motor and a ball screw mechanism.

The polishing-head shaft 11 is coupled to a polishing-head rotating device 20 disposed in the head arm 15. The polishing-head rotating device 20 is configured to rotate the polishing-head shaft 11 and the polishing head 1 about their own axes. The configuration of the polishing-head rotating device 20 is not particularly limited. In one example, the polishing-head rotating device 20 includes an electric motor, a belt, and pulleys.

The polishing apparatus further includes an operation controller 9 configured to control operations of each component of the polishing apparatus. The operation controller 9 is electrically coupled to the polishing head 1, the table motor 6, the polishing-head rotating device 20, the polishing-liquid supply nozzle 5, and the vertical moving mechanism 18, and controls operations of the polishing head 1, the table motor 6, the polishing-head rotating device 20, the polishing-liquid supply nozzle 5, and the vertical moving mechanism 18.

The operation controller 9 includes a memory 9a storing programs, and an arithmetic device 9b configured to perform arithmetic operations according to instructions contained in the programs. The operation controller 9 is composed of at least one computer. The memory 9a includes a main memory, such as a random-access memory (RAM), and an auxiliary memory, such as a hard disk drive (HDD) or a solid state drive (SSD). Examples of the arithmetic device 9b include a CPU (central processing unit) and a GPU (graphic processing unit). However, the specific configuration of the operation controller 9 is not limited to these examples.

Polishing of the wafer W is performed as follows. The operation controller 9 instructs the table motor 6, the polishing-head rotating device 20, and the polishing-liquid supply nozzle 5 to supply the polishing liquid onto the polishing surface 2a of the polishing pad 2 on the polishing table 3 from the polishing-liquid supply nozzle 5, while the polishing table 3 and the polishing head 1 are rotating in directions indicated by arrows in FIG. 1. The wafer W is pressed against the polishing surface 2a of the polishing pad 2 by the polishing head 1 in the presence of the polishing liquid between the polishing pad 2 and the wafer W, while the wafer W is being rotated by the polishing head 1. The surface of the wafer W is polished by a chemical action of the polishing liquid and mechanical action(s) of abrasive grains contained in the polishing liquid and/or the polishing pad 2.

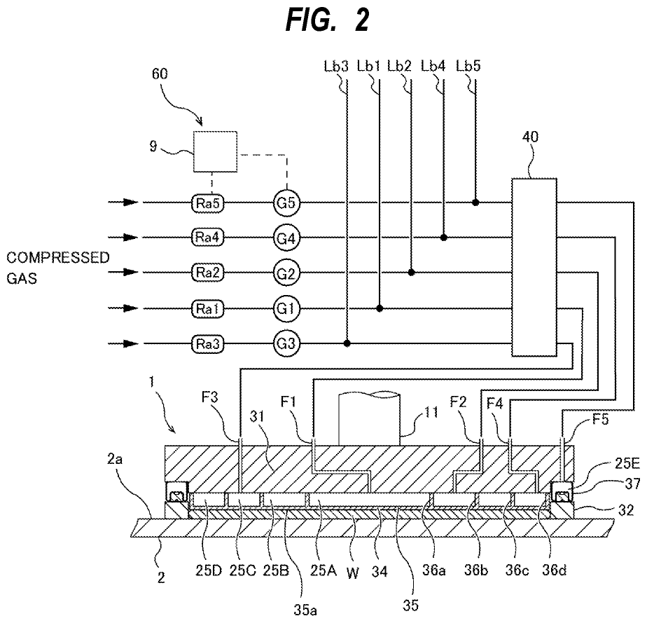

Next, the polishing head 1 will be described. FIG. 2 is a cross-sectional view showing an embodiment of the polishing head 1. The polishing head 1 includes a carrier 31 fixed to the end of the polishing-head shaft 11, an elastic membrane 34 attached to a lower portion of the carrier 31, and a retainer ring 32 arranged below the carrier 31. The retainer ring 32 is arranged around the elastic membrane 34. The retainer ring 32 is an annular structure configured to retain the wafer W so as to prevent the wafer W from being ejected from the polishing head 1 during polishing of the wafer W.

The elastic membrane 34 includes a contact portion 35 having a contact surface 35a which is contactable with an upper surface of the wafer W, and inner wall portions 36a, 36b, 36c and an outer wall portion 36d coupled to the contact portion 35. The contact portion 35 has substantially the same size and the same shape as those of the upper surface of the wafer W. The inner wall portions 36a, 36b, and 36c and the outer wall portion 36d are endless walls concentrically arranged. The outer wall portion 36d is located outwardly of the inner wall portions 36a, 36b, and 36c, and is arranged so as to surround the inner wall portions 36a, 36b, and 36c. In this embodiment, three inner wall portions 36a, 36b, and 36c are provided, while the invention is not limited to this embodiment. In one embodiment, two inner wall portions may be provided, or four or more inner wall portions may be provided.

A plurality of pressure chambers (in this embodiment, four pressure chambers) 25A, 25B, 25C, and 25D are provided between the elastic membrane 34 and the carrier 31. The pressure chambers 25A, 25B, 25C, and 25D are formed by the contact portion 35, the inner wall portions 36a, 36b, and 36c, and the outer wall portion 36d of the elastic membrane 34. Specifically, the pressure chamber 25A is located inwardly of the inner wall portion 36a, the pressure chamber 25B is located between the inner wall portion 36a and the inner wall portion 36b, the pressure chamber 25C is located between the inner wall portion 36b and the inner wall portion 36c, and the pressure chamber 25D is located between the inner wall portion 36c and the outer wall portion 36d. Sizes of the pressure chambers 25A, 25B, 25C, and 25D, i.e., distances from the center of the elastic membrane 34 to the inner wall portions 36a, 36b, 36c, and the outer wall 36d are not particularly limited. For example, the inner wall portions 36a, 36b, and 36c and the outer wall portion 36d may be arranged at equal intervals, or may be arranged at different intervals.

The pressure chamber 25A located in the center of the elastic membrane 34 has a circular shape, while the other pressure chambers 25B, 25C, and 25D have annular shapes. These pressure chambers 25A, 25B, 25C, and 25D are concentrically arranged. The pressure chamber 25B is located outwardly of the pressure chamber 25A, the pressure chamber 25C is located outwardly of the pressure chamber 25B, and the pressure chamber 25D is located outwardly of the pressure chamber 25C. The pressure chamber 25B is adjacent to the pressure chamber 25A, the pressure chamber 25C is adjacent to the pressure chamber 25B, and the pressure chamber 25D is adjacent to the pressure chamber 25C. In this embodiment, the elastic membrane 34 forms four pressure chambers 25A to 25D, while in one embodiment, the elastic membrane 34 may form three pressure chambers, or five or more pressure chambers.

An annular membrane (rolling diaphragm) 37 is arranged between the carrier 31 and the retainer ring 32. A pressure chamber 25E is formed inside the membrane 37. Gas delivery lines F1, F2, F3, F4, and F5 are coupled to the pressure chambers 25A, 25B, 25C, 25D, and 25E, respectively. The gas delivery lines F1, F2, F3, F4, and F5 extend through a rotary joint 40 attached to the polishing-head shaft 11.

The gas delivery lines F1, F2, F3, F4, and F5 are coupled to a compressed-gas source (not shown) which is a utility supply source provided in a factory where the polishing apparatus is installed. Compressed gas, such as compressed air, is supplied to the pressure chambers 25A, 25B, 25C, 25D, and 25E through the gas delivery lines F1, F2, F3, F4, and F5, respectively.

Pressure regulators Ra1, Ra2, Ra3, Ra4, and Ra5 are attached to the gas delivery lines F1, F2, F3, F4, and F5, respectively. The compressed gas from the compressed-gas supply source is independently supplied into the pressure chambers 25A to 25E through the pressure regulators Ra1 to Ra5 and the gas delivery lines F1 to F5. The pressure regulators Ra1 to Ra5 are configured to regulate pressures of the compressed gas in the pressure chambers 25A to 25E.

The pressure regulators Ra1 to Ra5 are coupled to the operation controller 9. Operations of the pressure regulators Ra1 to Ra5 are controlled by the operation controller 9. The operation controller 9 transmits individual pressure command values for the pressure chambers 25A to 25E to the pressure regulators Ra1 to Ra5, and the pressure regulators Ra1 to Ra5 operate so as to maintain the pressures in the pressure chambers 25A to 25E at the corresponding pressure command values.

The pressure regulators Ra1 to Ra5 can change the pressures in the pressure chambers 25A to 25E independently of each other. Therefore, the polishing head 1 can independently regulate polishing pressures on four corresponding regions of the wafer W (i.e., a central portion, an inner intermediate portion, an outer intermediate portion, and an edge portion) and a pressing force of the retainer ring 32 against the polishing surface 2a of the polishing pad 2. For example, the polishing head 1 can press different regions of the surface of the wafer W against the polishing surface 2a of the polishing pad 2 with different polishing pressures. Therefore, the polishing head 1 can control a film-thickness profile of the wafer W to achieve a target film-thickness profile.

Flow meters G1, G2, G3, G4, and G5 are attached to the gas delivery lines F1, F2, F3, F4, and F5, respectively. The flow meters G1, G2, G3, G4, and G5 are configured to measure flow rates of the compressed gas flowing through the gas delivery lines F1 to F5, respectively. The flow meters G1, G2, G3, G4, and G5 are coupled to the operation controller 9, and measurement values of the flow rates of the compressed gas flowing through the gas delivery lines F1, F2, F3, F4, and F5 are transmitted to the operation controller 9.

In this embodiment, a pressure controlling system 60 configured to control the pressures in the pressure chambers 25A to 25E includes the pressure regulators Ra1 to Ra5, the flow meters G1 to G5, and the operation controller 9 configured to control the operations of the pressure regulators Ra1 to Ra5. The operation controller 9 is configured to control the overall operations of the polishing apparatus. In one embodiment, the pressure controlling system 60 may include a dedicated operation controller configured to control the operations of the pressure regulators Ra1 to Ra5 instead of the operation controller 9. In this case, the dedicated operation controller includes a memory storing programs, and an arithmetic device configured to perform arithmetic operations according to instructions contained in the programs, as well as the above-described operation controller 9.

The gas delivery lines F1, F2, F3, F4, and F5 are coupled to vacuum lines Lb1, Lb2, Lb3, Lb4, and Lb5, respectively, at locations upstream of the rotary joint 40. The vacuum lines Lb1, Lb2, Lb3, Lb4, and Lb5 communicate with the pressure chambers 25A to 25E through the gas delivery lines F1, F2, F3, F4, and F5, respectively, and can form vacuum in the pressure chambers 25A to 25E.

In one embodiment in which the polishing head 1 holds the wafer W, vacuum is formed in the pressure chambers 25A, 25B, and 25C when the contact portion 35 of the elastic membrane 34 is in contact with the wafer W. The contact portion 35 of the elastic membrane 34 does not have a through-hole that allows fluid to flow out and flow in. Therefore, portions of the contact portions 35 forming these pressure chambers 25A, 25B, and 25C are recessed upward by the vacuum, so that the polishing head 1 can attract the wafer W via a suction cup effect of the elastic membrane 34.

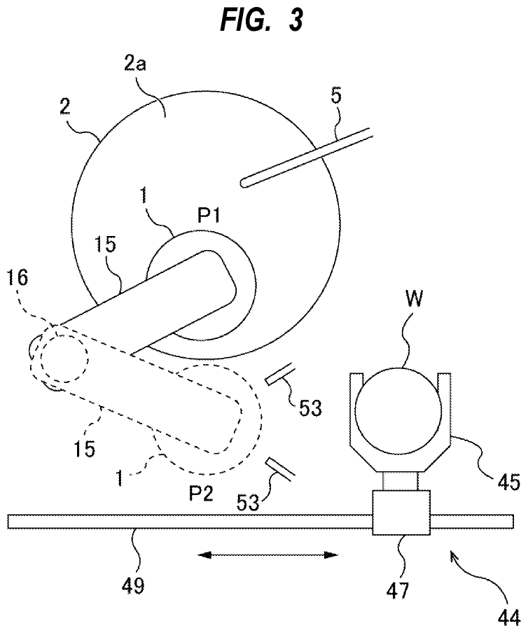

FIG. 3 is a plan view of a transfer device 44 configured to transfer the wafer W to the polishing head 1 shown in FIG. 1. As shown in FIG. 3, the wafer W is transferred to the polishing head 1 by the transfer device 44. The polishing head 1 is movable between a polishing position P1 indicated by a solid line in FIG. 3 and a transfer position P2 indicated by a dotted line. More specifically, the head arm 15 rotates about the support shaft 16, so that the polishing head 1 can move between the polishing position P1 and the transfer position P2. The polishing position P1 is located above the polishing surface 2a of the polishing pad 2, and the transfer position P2 is located outwardly of the polishing surface 2a.

The transfer device 44 includes a transfer stage 45 on which the wafer W is placed, an elevating device 47 configured to vertically move the transfer stage 45, and a horizontally-moving device 49 configured to horizontally move the transfer stage 45 and the elevating device 47 together. The wafer W to be polished is placed on the transfer stage 45, and is moved together with the transfer stage 45 to the transfer position P2 by the horizontally-moving device 49. When the polishing head 1 is placed in the transfer position P2, the elevating device 47 raises the transfer stage 45. The polishing head 1 holds the wafer W on the transfer stage 45, and moves to the polishing position P1 together with the wafer W.

The polishing-liquid supply nozzle 5 supplies the polishing liquid onto the polishing surface 2a of the rotating polishing pad 2, while the polishing head 1 presses the wafer W against the polishing surface 2a of the polishing pad 2 while rotating the wafer W to bring the wafer W into sliding contact with the polishing surface 2a. A lower surface of the wafer W is polished by the chemical action of the polishing liquid and the mechanical action(s) of the abrasive grains contained in the polishing liquid and/or the polishing pad 2.

After the polishing of the wafer W, the polishing head 1 moves to the transfer position P2 together with the wafer W. The polishing head 1 then transfers the polished wafer W to the transfer stage 45. The transfer stage 45 moves the wafer W to a next process. Cleaning nozzles 53 configured to supply a liquid (e.g., a rinsing liquid, such as pure water) onto the polishing head 1 to clean the polishing head 1 are disposed at the transfer position P2. The cleaning nozzles 53 are oriented toward the polishing head 1. The polishing head 1 which has released the wafer W is cleaned with the liquid supplied from the cleaning nozzles 53.

During the cleaning of the polishing head 1, a next wafer to be polished is moved to the transfer position P2 below the polishing head 1 by the transfer stage 45. When the cleaning of the polishing head 1 is terminated, the elevating device 47 raises the transfer stage 45 on which the next wafer has been placed. The cleaned polishing head 1 then holds the next wafer, and moves to the polishing position P1.

In this manner, multiple wafers are continuously polished.

However, during the cleaning of the polishing head 1, since the next wafer to be polished is moved to the transfer position P2 below the polishing head 1, the liquid may fall on the upper surface of the wafer in the transfer position P2. The liquid present on the upper surface of the wafer may prevent the polishing head 1 from applying appropriate force to the wafer, as described with reference to FIG. 24. One solution is to move the next wafer to the transfer position P2 after the cleaning of the polishing head 1 terminated. However, such an operation may lower a throughput of the polishing apparatus.

Furthermore, when the polishing head 1 attracts the wafer via the suction cup effect of the elastic membrane 34 to hold the next wafer, gas, such as air, may be present between the upper surface of the wafer and the elastic membrane 34 of the polishing head 1. The gas present on the upper surface of the wafer may also prevent the polishing head 1 from applying appropriate force to the wafer, as described with reference to FIG. 24.

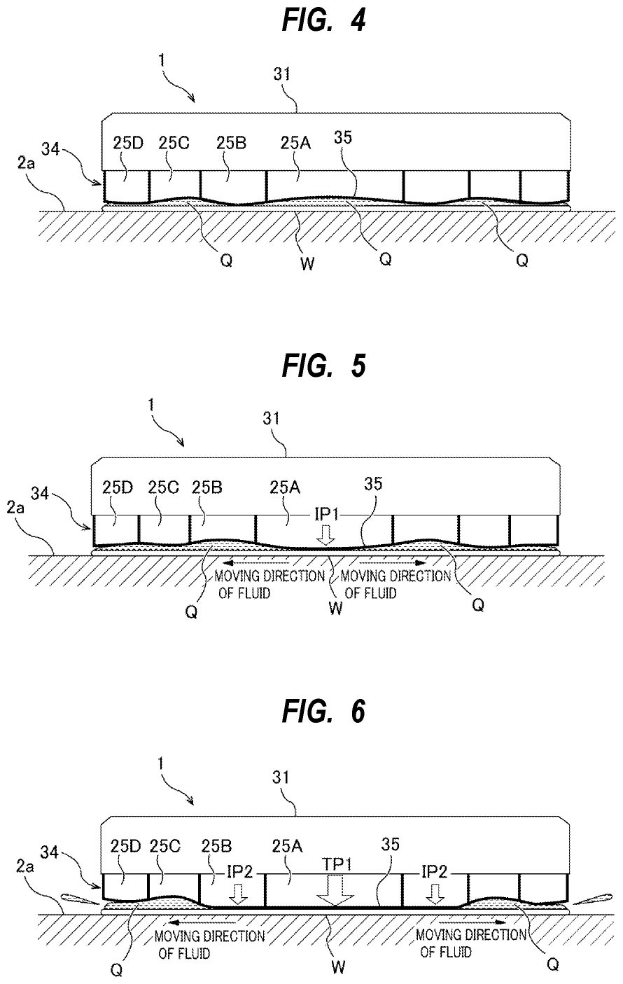

Thus, in this embodiment, the fluid is forced to flow out from the upper surface of the wafer as follows. FIG. 4 is a schematic diagram illustrating fluid Q present on the upper surface of the wafer W. In FIG. 4, depiction of the detailed configurations of the polishing head 1 is omitted. The polishing head 1 holding the wafer W to be polished is touched down on the polishing surface 2a of the polishing pad 2 by the vertically moving mechanism 18 (see FIG. 1). When the polishing head 1 is touched down on the polishing surface 2a, the polishing head 1 releases the negative pressures formed in the pressure chambers 25A, 25B, and 25C for attracting the wafer W. FIG. 4 illustrates a state in which the negative pressures formed in the pressure chambers 25A, 25B, and 25C of the polishing head 1 are removed, and the fluid Q is present on the upper surface of the wafer W, i.e., between the wafer W and the elastic membrane 34.

In this embodiment, before polishing of the wafer W, the pressures in the plurality of pressure chambers 25A to 25D formed by the elastic membrane 34 of the polishing head 1 are sequentially changed so as to force the fluid Q on the upper surface of the wafer W to move outward, so that the fluid Q is caused to flow out from the upper surface of the wafer W.

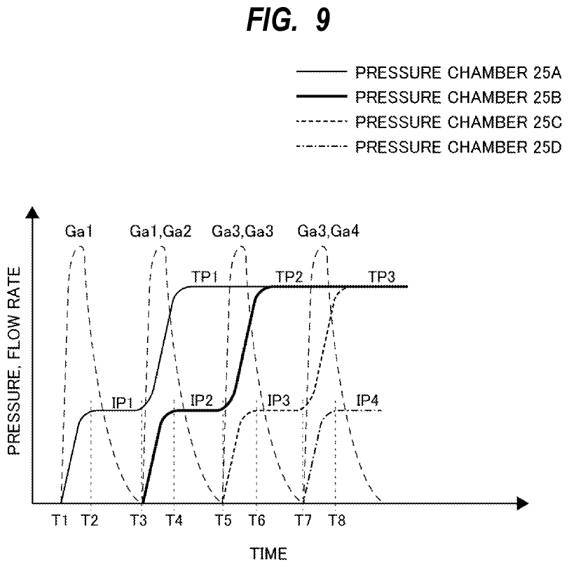

FIGS. 5 to 8 are schematic diagrams illustrating an embodiment in which the elastic membrane 34 of the polishing head 1 moves the fluid Q present on the upper surface of the wafer W outward until the fluid Q flows out from the upper surface of the wafer W. FIG. 9 is a graph showing a relationship between pressures in the plurality of pressure chambers 25A to 25D and time in this embodiment. In FIG. 9, a solid line represents pressure that changes over time in the pressure chamber 25A, a thick line represents pressure that changes over time in the pressure chamber 25B, a dashed line represents pressure that changes over time in the pressure chamber 25C, and a dash-dot-dash line represents pressure that changes over time in the pressure chamber 25D.

First, as shown in FIG. 5, the pressure controlling system 60 operates the pressure regulator Ra1 to start pressurizing the pressure chamber 25A located in the center of the polishing head 1, so that a pressure IP1 is formed in the pressure chamber 25A. A point in time at which the pressurization of the pressure chamber 25A is started is a point in time T1 in FIG. 9. After the pressure in the pressure chamber 25A reaches the pressure IP1 at a point in time T2 shown in FIG. 9, the pressure controlling system 60 maintains the pressure IP1 in the pressure chamber 25A for a predetermined period of time T2 to T3 (see FIG. 9). The pressure IP1 is an initial pressure in the pressure chamber 25A. The pressure IP1 formed in the pressure chamber 25A can cause the fluid Q present between the upper surface of the wafer W and the pressure chamber 25A to move outward (i.e., from the pressure chamber 25A toward the pressure chamber 25B). When the pressure chamber 25A is pressurized to reach the pressure IP1, pressurization of the pressure chamber 25B by the pressure controlling system 60 has not yet been started.

Next, as shown in FIG. 6, the pressure controlling system 60 operates the pressure regulator Ra1 to increase the pressure in the pressure chamber 25A from the pressure IP1 to a target pressure TP1, while the pressure controlling system 60 operates the pressure regulator Ra2 to pressurize the pressure chamber 25B to form a pressure IP2 in the pressure chamber 25B which is lower than the target pressure TP1 in the pressure chamber 25A. With such an operation, the fluid Q present between the upper surface of the wafer W and the pressure chamber 25B is moved outward (i.e., from the pressure chamber 25B toward the pressure chamber 25C). The target pressure TP1 in the pressure chamber 25A is higher than the pressure (initial pressure) IP1. The pressure IP2 in the pressure chamber 25B is an initial pressure in the pressure chamber 25B, which is lower than the target pressure TP1 in the pressure chamber 25A. The pressure IP1, the target pressure TP1, and the pressure IP2 are positive pressures which are higher than atmospheric pressure.

The pressure IP2 in the pressure chamber 25B is the same as the pressure IP1 in the pressure chamber 25A. In one embodiment, the pressure IP2 in the pressure chamber 25B may be different from the pressure IP1 in the pressure chamber 25A as long as the pressure IP2 is lower than the target pressure TP1 in the pressure chamber 25A. After the pressure in the pressure chamber 25A has reached the target pressure TP1, the pressure controlling system 60 maintains the target pressure TP1 in the pressure chamber 25A.

A point in time at which the pressurization of the pressure chamber 25B is started is a point in time T3 in FIG. 9. After the pressure in the pressure chamber 25B reaches the pressure IP2 at a point in time T4 shown in FIG. 9, the pressure controlling system 60 maintains the pressure IP2 in the pressure chamber 25B for a predetermined period of time T4 to T5 (see FIG. 9). The operation of increasing the pressure in the pressure chamber 25A from the pressure IP1 to the target pressure TP1 is started at the same time as the pressurization of the pressure chamber 25B is started. Specifically, the pressure controlling system 60 starts increasing the pressure in the pressure chamber 25A and starts pressurizing the pressure chamber 25B at the point in time T3. In one embodiment, the operation of increasing the pressure in the pressure chamber 25A from the pressure IP1 to the target pressure TP1 may be started before the pressurization of the pressure chamber 25B is started. Specifically, the pressure controlling system 60 may start increasing the pressure in the pressure chamber 25A at a point in time before the point in time T3 at which the pressurization of the pressure chamber 25B is started.

In one embodiment, the operation of pressurizing the pressure chamber 25A during pressurizing of the pressure chamber 25B may be performed as follows. The operation controller 9 of the pressure controlling system 60 may monitor a flow rate of the compressed gas to be supplied to the pressure chamber 25B based on a measurement value obtained by the flow meter G2, and the pressure controlling system 60 may keep supplying the compressed gas to the pressure chamber 25A while the compressed gas is supplied to the pressure chamber 25B. In FIG. 9, reference symbols Ga1, Ga2, Ga3, and Ga4 represent flow rates of the compressed gas to be supplied to the pressure chambers 25A, 25B, 25C, and 25D, respectively.

In this way, if the supply of the compressed gas to the pressure chamber 25A is continued as long as the compressed gas is supplied to the pressure chamber 25B, the pressure in the pressure chamber 25A may become higher than the target pressure TP1. In that case, for example, the pressure in the pressure chamber 25A is reduced before a next step (i.e., a pressurizing operation of the pressure chamber 25C).

As will be described later, the supply of the compressed gas to the pressure chamber 25A may be continued while the pressure in the pressure chamber 25B is increased during pressurizing of the pressure chamber 25C. In that case, for example, the pressure in the pressure chamber 25A is reduced before a next step (i.e., a pressurizing operation of the pressure chamber 25D located outwardly of the pressure chamber 25C).

The above-described embodiment in which the supply of the compressed gas to the inner pressure chamber is continued while the compressed gas is supplied to the outer pressure chamber (e.g., while the flow rate of the compressed gas to be supplied to the outer pressure chamber is larger than a threshold value) may be applied to steps and embodiments described below.

According to this embodiment, the pressure controlling system 60 pressurizes the pressure chamber 25B to form the pressure IP2 in the pressure chamber 25B which is lower than the target pressure TP1 when the pressure equal to or higher than the target pressure TP1 is formed in the pressure chamber 25A. As can be seen from FIG. 9, while the pressure chamber 25B is pressurized, the pressure in the pressure chamber 25A is kept higher than the pressure in the pressure chamber 25B. Such a pressure difference keeps the contact portion 35 of the elastic membrane 34 forming the pressure chamber 25A in tight contact with the upper surface of the wafer W. Therefore, the fluid Q is prevented from flowing backward from the pressure chamber 25B toward the pressure chamber 25A.

After the operation shown in FIG. 6, as shown in FIG. 7, the pressure controlling system 60 operates the pressure regulator Ra2 to increase the pressure in the pressure chamber 25B from the pressure IP2 to a target pressure TP2, while the pressure controlling system 60 operates the pressure regulator Ra3 to pressurize the pressure chamber 25C to form a pressure IP3 in the pressure chamber 25C which is lower than the target pressure TP2 in the pressure chamber 25B. With such an operation, the fluid Q present between the upper surface of the wafer W and the pressure chamber 25C is moved outward (i.e., from the pressure chamber 25C toward the pressure chamber 25D). The target pressure TP2 in the pressure chamber 25B is higher than the pressure (initial pressure) IP2. The pressure IP3 in the pressure chamber 25C is an initial pressure in the pressure chamber 25C, which is lower than the target pressure TP2 in the pressure chamber 25B. The target pressure TP2 and the pressure IP3 are positive pressures which are higher than atmospheric pressure.

The target pressure TP2 in the pressure chamber 25B is the same as the target pressure TP1 in the pressure chamber 25A. In one embodiment, the target pressure TP2 in the pressure chamber 25B may be different from the target pressure TP1 in the pressure chamber 25A. The pressure IP3 in the pressure chamber 25C is the same as the pressure IP2 in the pressure chamber 25B. In one embodiment, the pressure IP3 in the pressure chamber 25C may be different from the pressure IP2 in the pressure chamber 25B as long as the pressure IP3 is lower than the target pressure TP2 in the pressure chamber 25B. After the pressure in the pressure chamber 25B has reached the target pressure TP2, the pressure controlling system 60 maintains the target pressure TP2 in the pressure chamber 25B.

A point in time at which the pressurization of the pressure chamber 25C is started is a point in time T5 in FIG. 9. After the pressure in the pressure chamber 25C reaches the pressure IP3 at a point in time T6 shown in FIG. 9, the pressure controlling system 60 maintains the pressure IP3 in the pressure chamber 25C for a predetermined period of time T6 to T7 (see FIG. 9). The operation of increasing the pressure in the pressure chamber 25B from the pressure IP2 to the target pressure TP2 is started at the same time as the pressurization of the pressure chamber 25C is started. Specifically, the pressure controlling system 60 starts increasing the pressure in the pressure chamber 25B and starts pressurizing the pressure chamber 25C at the point in time T5. In one embodiment, the operation of increasing the pressure in the pressure chamber 25B from the pressure IP2 to the target pressure TP2 may be started before the pressurization of the pressure chamber 25C is started. Specifically, the pressure controlling system 60 may start increasing the pressure in the pressure chamber 25B at a point in time before the point in time T5 at which the pressurization of the pressure chamber 25C is started.

As shown in FIG. 7, the pressure controlling system 60 pressurizes the pressure chamber 25C to form the pressure IP3 in the pressure chamber 25C which is lower than the target pressure TP2 when the target pressure TP2 is formed in the pressure chamber 25B. As can be seen from FIG. 9, while the pressure chamber 25C is pressurized, the pressure in the pressure chamber 25B is kept higher than the pressure in the pressure chamber 25C. Such a pressure difference keeps the contact portion 35 of the elastic membrane 34 forming the pressure chamber 25B in tight contact with the upper surface of the wafer W. Therefore, the fluid Q is prevented from flowing backward from the pressure chamber 25C toward the pressure chamber 25B.

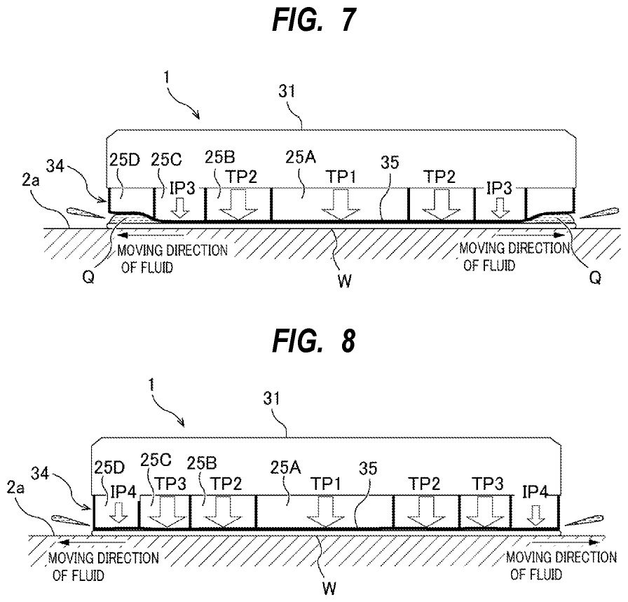

Next, as shown in FIG. 8, the pressure controlling system 60 operates the pressure regulator Ra3 to increase the pressure in the pressure chamber 25C from the pressure IP3 to a target pressure TP3, while the pressure controlling system 60 operates the pressure regulator Ra4 to pressurize the pressure chamber 25D to form a pressure IP4 in the pressure chamber 25D which is lower than the target pressure TP3. With such an operation, the fluid Q present between the upper surface of the wafer W and the pressure chamber 25D is moved outside the wafer W. The target pressure TP3 in the pressure chamber 25C is higher than the pressure (initial pressure) IP3. The pressure IP4 in the pressure chamber 25D is an initial pressure of the pressure chamber 25D, which is lower than the target pressure TP3 in the pressure chamber 25C. The target pressure TP3 and the pressure TP4 are positive pressures which are higher than atmospheric pressure.

The target pressure TP3 in the pressure chamber 25C is the same as the target pressure TP2 in the pressure chamber 25B. In one embodiment, the target pressure TP3 in the pressure chamber 25C 5 may be different from the target pressure TP2 in the pressure chamber 25B. The pressure TP4 in the pressure chamber 25D is the same as the pressure IP3 in the pressure chamber 25C. In one embodiment, the pressure IP4 in the pressure chamber 25D may be different from the pressure IP3 in the pressure chamber 25C as long as the pressure IP4 is lower than the target pressure TP3 in the pressure chamber 25C. After the pressure in the pressure chamber 25C has reached the target pressure TP3, the pressure controlling system 60 maintains the target pressure TP3 in the pressure chamber 25C.

A point in time at which the pressurization of the pressure chamber 25D is started is a point in time T7 in FIG. 9. After the pressure in the pressure chamber 25D reaches the pressure TP4 at a point in time T8 shown in FIG. 9, the pressure controlling system 60 maintains the pressure TP4 in the pressure chamber 25D (see FIG. 9). The operation of increasing the pressure in the pressure chamber 25C from the pressure IP3 to the target pressure TP3 is started at the same time as the pressurization of the pressure chamber 25D is started. Specifically, the pressure controlling system 60 starts increasing the pressure in the pressure chamber 25C and starts pressurizing the pressure chamber 25D at the point in time T7. In one embodiment, the operation of increasing the pressure in the pressure chamber 25C from the pressure IP3 to the target pressure TP3 may be started before the pressurization of the pressure chamber 25D is started. Specifically, the pressure controlling system 60 may start increasing the pressure in the pressure chamber 25C at a point in time before the point in time T7 at which the pressurization of the pressure chamber 25D is started.

As shown in FIG. 8, the pressure controlling system 60 pressurizes the pressure chamber 25D to form the pressure TP4 in the pressure chamber 25D which is lower than the target pressure TP3 when the target pressure TP3 is formed in the pressure chamber 25C. As can be seen from FIG. 9, while the pressure chamber 25D is pressurized, the pressure in the pressure chamber 25C is kept higher than the pressure in the pressure chamber 25D. Such a pressure difference keeps the contact portion 35 of the elastic membrane 34 forming the pressure chamber 25C in tight contact with the upper surface of the wafer W. Therefore, the fluid Q is prevented from flowing backward from the pressure chamber 25D toward the pressure chamber 25C.

With the operations shown in FIGS. 5 to 8, the fluid Q present between the upper surface of the wafer W and the elastic membrane 34 of the polishing head 1 is pushed outward by the elastic membrane 34 and is removed from the wafer W. The pressure controlling system 60 then forms polishing pressures required to polish the wafer W in the pressure chambers 25A to 25D, so that the polishing head 1 can press the lower surface of the wafer W against the polishing surface 2a of the polishing pad 2 with the elastic membrane 34 to polish the lower surface of the wafer W. The polishing head 1 can apply intended pressures to the regions of the wafer W corresponding to the pressure chambers 25A to 25D.

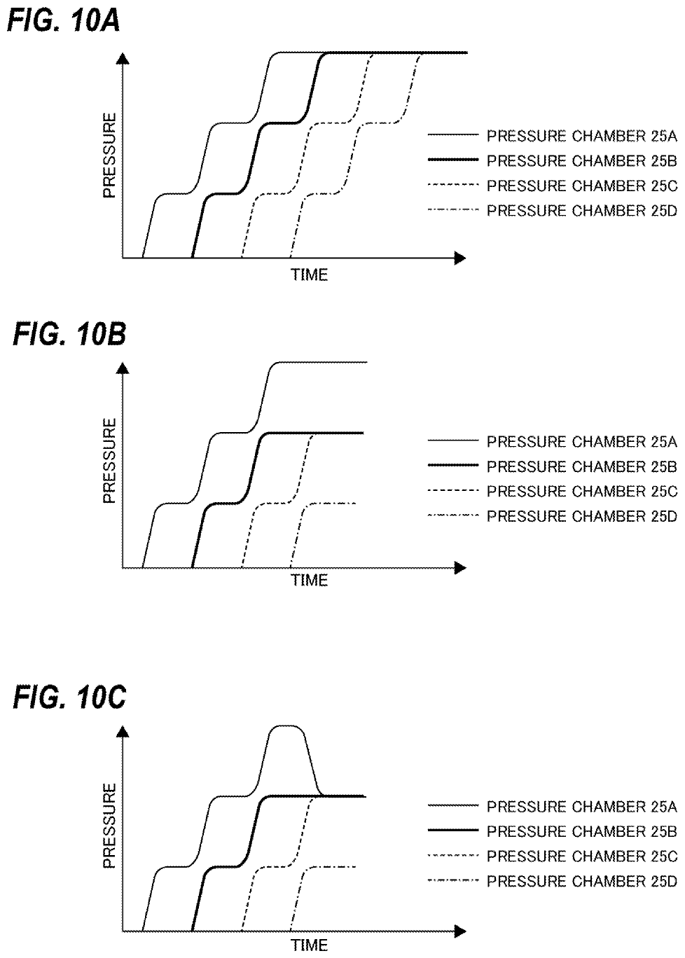

In the above-described embodiment, the pressures in the pressure chambers 25A to 25C are increased in two stages, while the pressures in the pressure chambers 25A to 25C may be increased in multiple stages which are three or more stages. The pressure in the pressure chamber 25D may also be increased in multiple stages which are two or more stages. For example, FIG. 10A shows an example in which the pressures in the pressure chambers 25A to 25D are increased in three stages. FIG. 10B shows an example in which the pressure in the pressure chamber 25A is increased in three stages, the pressures in the pressure chamber 25B and 25C are increased in two stages, and the pressure in the pressure chamber 25D is increased in one stage. FIG. 10C shows an example in which the pressure in the pressure chamber 25A is increased in three steps and is then reduced, and the pressures in the pressure chambers 25B and 25C are increased in two stages.

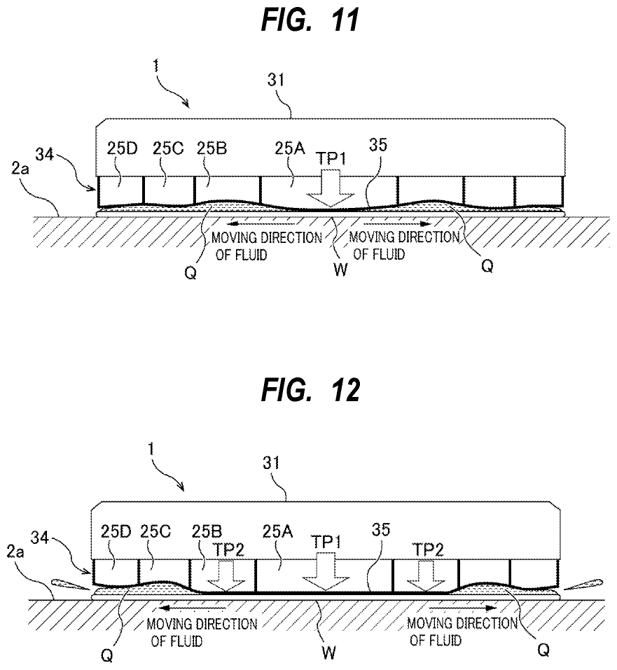

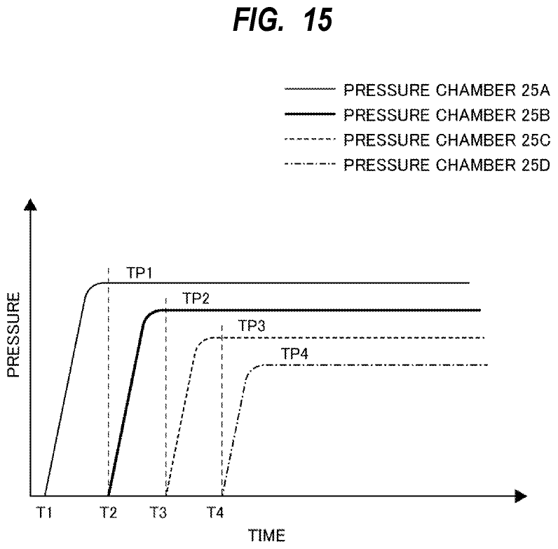

Next, another embodiment in which the fluid is removed from the upper surface of the wafer W will be described. FIGS. 11 to 14 are schematic diagrams illustrating another embodiment in which the elastic membrane 34 of the polishing head 1 moves the fluid Q present on the upper surface of the wafer W outward until the fluid Q flows out from the upper surface of the wafer W. FIG. 15 is a graph showing a relationship between pressures in the pressure chambers 25A to 25D and time in this embodiment. In FIG. 15, a solid line represents pressure that changes over time in the pressure chamber 25A, a thick line represents pressure that changes over time in the pressure chamber 25B, a dashed line represents pressure that changes over time in the pressure chamber 25C, and a dash-dot-dash line represents pressure that changes over time in the pressure chamber 25D.

First, as shown in FIG. 11, the pressure controlling system 60 operates the pressure regulator Ra1 to start pressurizing the pressure chamber 25A located in the center of the polishing head 1, so that a target pressure TP1 is formed in the pressure chamber 25A. A point in time at which the pressurization of the pressure chamber 25A is started is a point in time T1 in FIG. 15. After the pressure in the pressure chamber 25A has reached the target pressure TP1, the pressure controlling system 60 maintains the target pressure TP1 in the pressure chamber 25A (see FIG. 15). The target pressure TP1 formed in the pressure chamber 25A can cause the fluid Q present between the upper surface of the wafer W and the pressure chamber 25A to move outward (i.e., from the pressure chamber 25A toward the pressure chamber 25B). When the pressure chamber 25A is pressurized to reach the target pressure TP1, pressurization of the pressure chamber 25B by the pressure controlling system 60 has not yet been started.

Next, as shown in FIG. 12, the pressure controlling system 60 operates the pressure regulator Ra2 to pressurize the pressure chamber 25B to form a target pressure TP2 in the pressure chamber 25B which is lower than the target pressure TP1. With such an operation, the fluid Q present between the upper surface of the wafer W and the pressure chamber 25B is moved outward (i.e., from the pressure chamber 25B toward the pressure chamber 25C). While the pressure chamber 25B is pressurized to the target pressure TP2, the target pressure TP1 in the pressure chamber 25A is maintained. The target pressures TP1 and TP2 are positive pressures which are higher than atmospheric pressure. A point in time at which the pressurization of the pressure chamber 25B is started is a point in time T2 in FIG. 15, which is a point in time at which the target pressure TP1 is being formed in the pressure chamber 25A.

After the pressure in the pressure chamber 25B has reached the target pressure TP2, the pressure controlling system 60 maintains the target pressure TP2 in the pressure chamber 25B (see FIG. 15).

According to this embodiment, as shown in FIG. 12, the pressure controlling system 60 pressurizes the pressure chamber 25B to form the target pressure TP2 in the pressure chamber 25B which is lower than the target pressure TP1 when the target pressure TP1 is formed in the pressure chamber 25A. As can be seen from FIG. 15, while the pressure chamber 25B is pressurized, the pressure in the pressure chamber 25A is kept higher than the pressure in the pressure chamber 25B. Such a pressure difference keeps the contact portion 35 of the elastic membrane 34 forming the pressure chamber 25A in tight contact with the upper surface of the wafer W. Therefore, the fluid Q is prevented from flowing backward from the pressure chamber 25B toward the pressure chamber 25A.

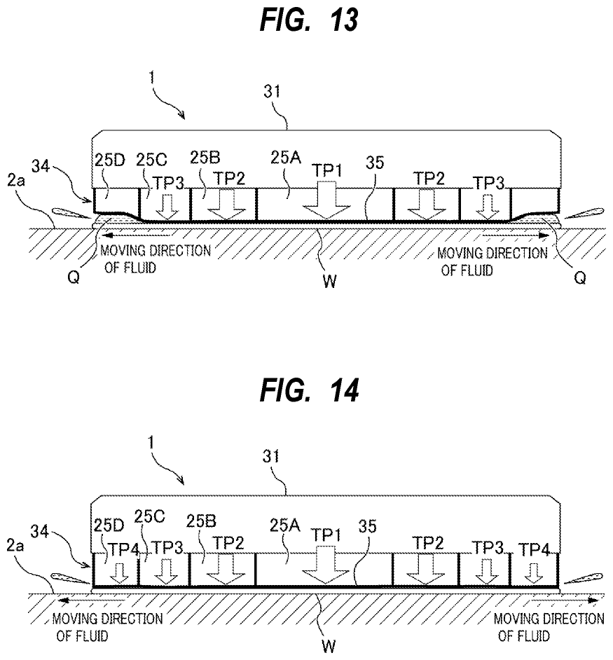

Next, as shown in FIG. 13, the pressure controlling system 60 operates the pressure regulator Ra3 to pressurize the pressure chamber 25C to form a target pressure TP3 in the pressure chamber 25C which is lower than the target pressure TP2. With such an operation, the fluid Q present between the upper surface of the wafer W and the pressure chamber 25C is moved outward (i.e., from the pressure chamber 25C toward the pressure chamber 25D). While the pressure chamber 25C is pressurized to the target pressure TP3, the target pressure TP2 in the pressure chamber 25B is maintained. The target pressure TP3 is a positive pressure which is higher than atmospheric pressure. A point in time at which the pressurization of the pressure chamber 25C is started is a point in time T3 in FIG. 15, which is a point in time at which the target pressure TP2 is being formed in the pressure chamber 25B. After the pressure in the pressure chamber 25C has reached the target pressure TP3, the pressure controlling system 60 maintains the target pressure TP3 in the pressure chamber 25C (see FIG. 15).

According to this embodiment, as shown in FIG. 13, the pressure controlling system 60 pressurizes the pressure chamber 25C to form the target pressure TP3 in the pressure chamber 25C which is lower than the target pressure TP2 when the target pressure TP2 is formed in the pressure chamber 25B. As can be seen from FIG. 15, while the pressure chamber 25C is pressurized, the pressure in the pressure chamber 25B is kept higher than the pressure in the pressure chamber 25C. Such a pressure difference keeps the contact portion 35 of the elastic membrane 34 forming the pressure chamber 25B in tight contact with the upper surface of the wafer W. Therefore, the fluid Q is prevented from flowing backward from the pressure chamber 25C toward the pressure chamber 25B.

Next, as shown in FIG. 14, the pressure controlling system 60 operates the pressure regulator Ra4 to pressurize the pressure chamber 25D to form a target pressure TP4 in the pressure chamber 25D which is lower than the target pressure TP3. With such an operation, the fluid Q present between the upper surface of the wafer W and the pressure chamber 25D is moved outside the wafer W. The target pressure TP4 is a positive pressure which is higher than atmospheric pressure. A point in time at which the pressurization of the pressure chamber 25D is started is a point in time T4 in FIG. 15, which is a point in time at which the target pressure TP3 is being formed in the pressure chamber 25C. After the pressure in the pressure chamber 25D has reached the target pressure TP4, the pressure controlling system 60 maintains the target pressure TP4 in the pressure chamber 25D (see FIG. 15).

According to this embodiment, as shown in FIG. 14, the pressure controlling system 60 pressurizes the pressure chamber 25D to form the target pressure TP4 in the pressure chamber 25D which is lower than the target pressure TP3 when the target pressure TP3 is formed in the pressure chamber 25C. As can be seen from FIG. 15, while the pressure chamber 25D is pressurized, the pressure in the pressure chamber 25C is kept higher than the pressure in the pressure chamber 25D. Such a pressure difference keeps the contact portion 35 of the elastic membrane 34 forming the pressure chamber 25C in tight contact with the upper surface of the wafer W. Therefore, the fluid Q is prevented from flowing backward from the pressure chamber 25D toward the pressure chamber 25C.

With the operations shown in FIGS. 11 to 14, the fluid Q present between the upper surface of the wafer W and the elastic membrane 34 of the polishing head 1 is pushed outward by the elastic membrane 34 and is discharged from the wafer W. The pressure controlling system 60 then forms polishing pressures required to polish the wafer W in the pressure chambers 25A to 25D, so that the polishing head 1 can press the lower surface of the wafer W against the polishing surface 2a of the polishing pad 2 with the elastic membrane 34 to polish the lower surface of the wafer W. The polishing head 1 can apply intended pressures to the regions of the wafer W corresponding to the pressure chambers 25A to 25D.

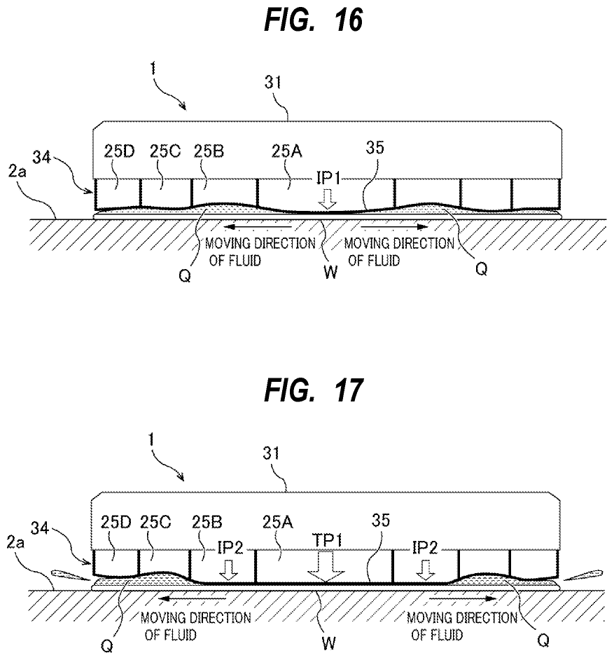

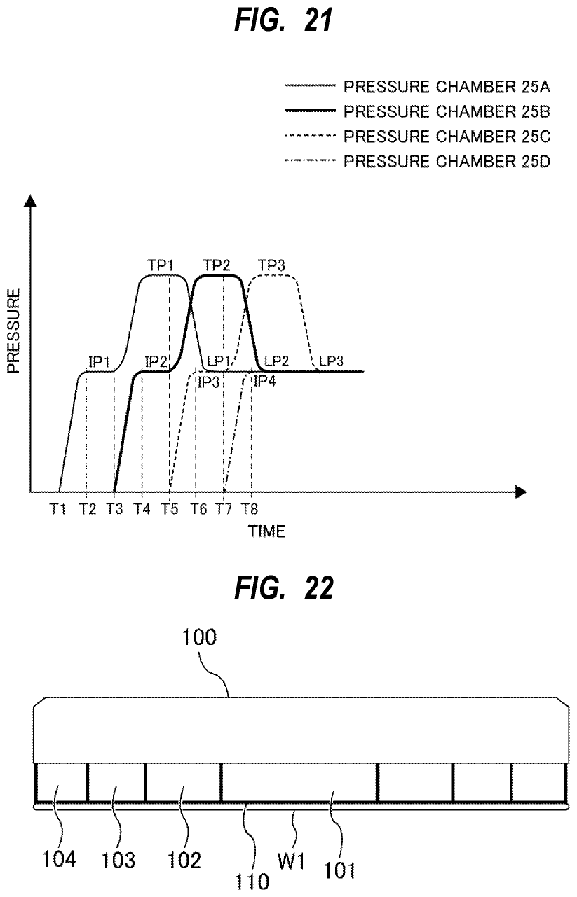

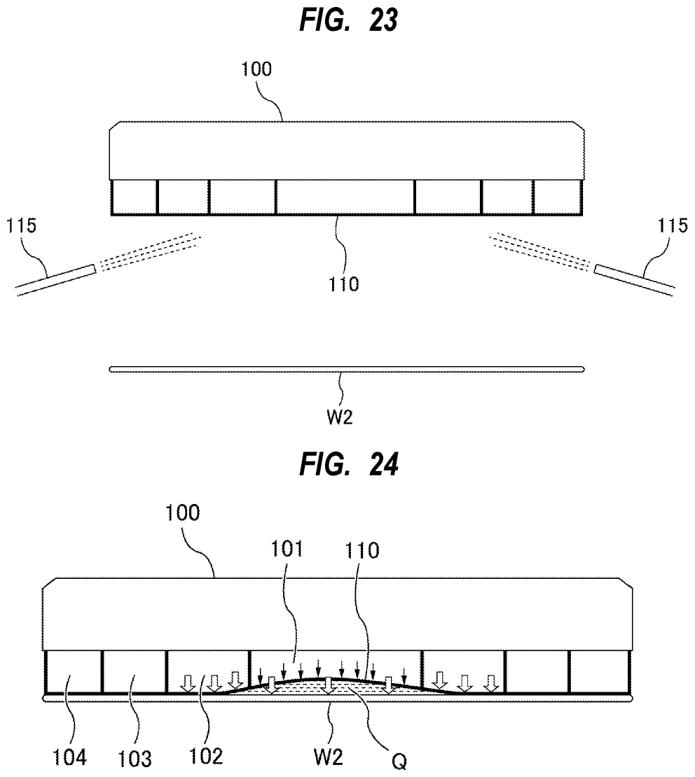

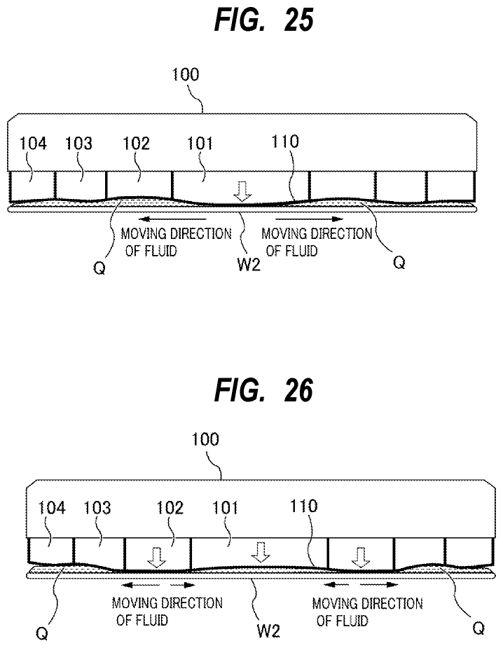

Next, another embodiment in which the fluid is removed from the upper surface of the wafer W will be described. FIGS. 16 to 20 are schematic diagrams illustrating another embodiment in which the elastic membrane 34 of the polishing head 1 moves the fluid Q present on the upper surface of the wafer W outward until the fluid Q flows out from the upper surface of the wafer W. FIG. 21 is a graph showing a relationship between pressures in the pressure chambers 25A to 25D and time in this embodiment. In FIG. 21, a solid line represents pressure that changes over time in the pressure chamber 25A, a thick line represents pressure that changes over time in the pressure chamber 25B, a dashed line represents pressure that changes over time in the pressure chamber 25C, and a dash-dot-dash line represents pressure that changes over time in the pressure chamber 25D.

Details of this embodiment, which will not be particularly described, are the same as those of the embodiment described with reference to FIGS. 5 to 9, and duplicated descriptions will be omitted.

First, as shown in FIG. 16, the pressure controlling system 60 operates the pressure regulator Ra1 to start pressurizing the pressure chamber 25A located in the center of the polishing head 1, so that a pressure IP1 is formed in the pressure chamber 25A. A point in time at which the pressurization of the pressure chamber 25A is started is a point in time T1 in FIG. 21. After the pressure in the pressure chamber 25A reaches the pressure IP1 at a point in time T2 shown in FIG. 21, the pressure controlling system 60 maintains the pressure IP1 in the pressure chamber 25A for a predetermined period of time T2 to T3 (see FIG. 21). The pressure IP1 formed in the pressure chamber 25A can cause the fluid Q present between the upper surface of the wafer W and the pressure chamber 25A to move outward (i.e., from the pressure chamber 25A toward the pressure chamber 25B).

Next, as shown in FIG. 17, the pressure controlling system 60 operates the pressure regulator Ra1 to increase the pressure in the pressure chamber 25A from the pressure IP1 to a target pressure TP1, while the pressure controlling system 60 operates the pressure regulator Ra2 to pressurize the pressure chamber 25B to form a pressure IP2 in the pressure chamber 25B which is lower than the target pressure TP1 of the pressure chamber 25A. With such an operation, the fluid Q present between the upper surface of the wafer W and the pressure chamber 25B is moved outward (i.e., from the pressure chamber 25B toward the pressure chamber 25C). After the pressure in the pressure chamber 25A has reached the target pressure TP1, the pressure controlling system 60 temporarily maintains the target pressure TP1 in the pressure chamber 25A.

A point in time at which the pressurization of the pressure chamber 25B is started is a point in time T3 in FIG. 21. After the pressure in the pressure chamber 25B reaches the pressure IP2 at a point in time T4 shown in FIG. 21, the pressure controlling system 60 maintains the pressure IP2 in the pressure chamber 25B for a predetermined period of time T4 to T5 (see FIG. 21). The operation of increasing the pressure in the pressure chamber 25A from the pressure IP1 to the target pressure TP1 is started at the same time as the pressurization of the pressure chamber 25B is started. Specifically, the pressure controlling system 60 starts increasing the pressure in the pressure chamber 25A and starts pressurizing the pressure chamber 25B at the point in time T3. In one embodiment, the operation of increasing the pressure in the pressure chamber 25A from the pressure IP1 to the target pressure TP1 may be started before the pressurization of the pressure chamber 25B is started. Specifically, the pressure controlling system 60 may start increasing the pressure in the pressure chamber 25A at a point in time before the point in time T3 at which the pressurization of the pressure chamber 25B is started.

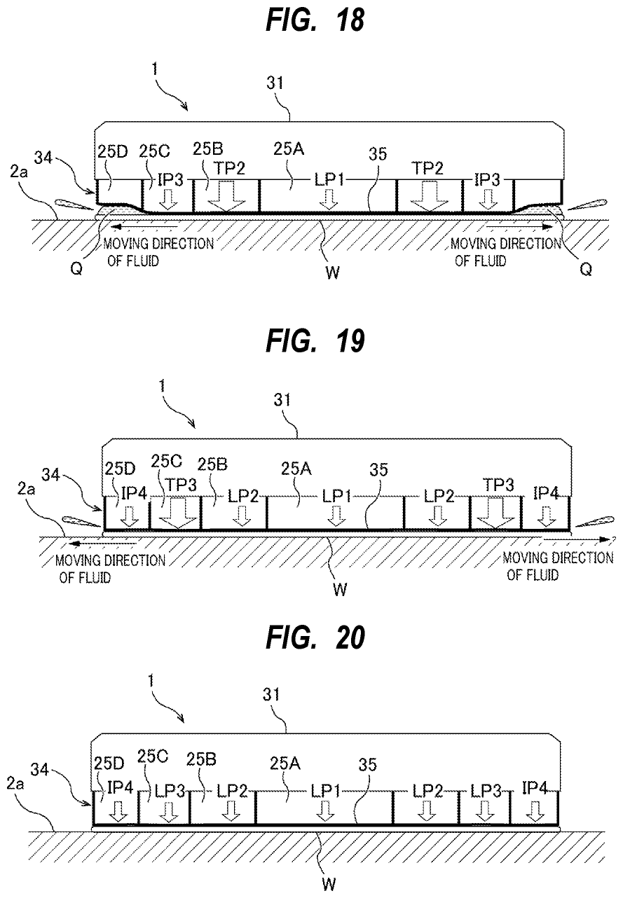

Next, as shown in FIG. 18, the pressure controlling system 60 operates the pressure regulator Ra2 to increase the pressure in the pressure chamber 25B from the pressure IP2 to a target pressure TP2, while the pressure controlling system 60 operates the pressure regulator Ra3 to pressurize the pressure chamber 25C to form a pressure IP3 in the pressure chamber 25C which is lower than the target pressure TP2 of the pressure chamber 25B. With such an operation, the fluid Q present between the upper surface of the wafer W and the pressure chamber 25C is moved outward (i.e., from the pressure chamber 25C toward the pressure chamber 25D). After the pressure in the pressure chamber 25B has reached the target pressure TP2, the pressure controlling system 60 temporarily maintains the target pressure TP2 in the pressure chamber 25B.

The pressure controlling system 60 operates the pressure regulator Ra1 to lower the pressure in the pressure chamber 25A from the target pressure TP1 to a preset pressure LP1, while the pressure controlling system 60 increases the pressure in the pressure chamber 25B from the pressure IP2 to the target pressure TP2. In one example, the pressure LP1 may be the same as the pressure (initial pressure) IP1, or may be different from the pressure (initial pressure) IP1. After the pressure in the pressure chamber 25A has been lowered to the pressure LP1, the pressure controlling system 60 maintains the pressure LP1 in the pressure chamber 25A. According to this embodiment, the pressure in the pressure chamber 25A is reduced, so that the polishing rate of the region of the wafer W corresponding to the pressure chamber 25A can be prevented from locally increasing before polishing of the wafer W is started.

The operation of lowering the pressure in the pressure chamber 25A from the target pressure TP1 to the pressure LP1 is started at the same time as or after the operation of increasing the pressure in the pressure chamber 25B from the pressure IP2 to the target pressure TP2 is started.

A point in time at which the pressurization of the pressure chamber 25C is started is a point in time T5 in FIG. 21. After the pressure in the pressure chamber 25C reaches a pressure IP3 at a point in time T6 shown in FIG. 21, the pressure controlling system 60 maintains the pressure IP3 in the pressure chamber 25C for a predetermined period of time T6 to T7 (see FIG. 21). The operation of increasing the pressure in the pressure chamber 25B from the pressure IP2 to the target pressure TP2 is started at the same time as the pressurization of the pressure chamber 25C is started. Specifically, the pressure controlling system 60 starts increasing the pressure in the pressure chamber 25B and starts pressurizing the pressure chamber 25C at the point in time T5. In one embodiment, the operation of increasing the pressure in the pressure chamber 25B from the pressure IP2 to the target pressure TP2 may be started before the pressurization of the pressure chamber 25C is started. Specifically, the pressure controlling system 60 may start increasing the pressure in the pressure chamber 25B at a point in time before the point in time T5 at which the pressurization of the pressure chamber 25C is started.

Next, as shown in FIG. 19, the pressure controlling system 60 operates the pressure regulator Ra3 to increase the pressure in the pressure chamber 25C from the pressure IP3 to a target pressure TP3, while the pressure controlling system 60 operates the pressure regulator Ra4 to pressurize the pressure chamber 25D to form a pressure IP4 in the pressure chamber 25D which is lower than the target pressure TP3 of the pressure chamber 25C. With such an operation, the fluid Q present between the upper surface of the wafer W and the pressure chamber 25D is moved outside the wafer W. After the pressure in the pressure chamber 25C has reached the target pressure TP3, the pressure controlling system 60 temporarily maintains the target pressure TP3 in the pressure chamber 25C.

The pressure controlling system 60 operates the pressure regulator Ra2 to lower the pressure in the pressure chamber 25B from the target pressure TP2 to a preset pressure LP2, while the pressure controlling system 60 increases the pressure in the pressure chamber 25C from the pressure IP3 to the target pressure TP3. In one example, the pressure LP2 may be the same as the pressure (initial pressure) IP2, or may be different from the pressure (initial pressure) IP2. After the pressure in the pressure chamber 25B has been lowered to the pressure LP2, the pressure controlling system 60 maintains the pressure LP2 in the pressure chamber 25B. According to this embodiment, the pressure in the pressure chamber 25B is reduced, so that the polishing rate of the region of the wafer W corresponding to the pressure chamber 25B can be prevented from locally increasing before polishing of the wafer W is started.

The operation of lowering the pressure in the pressure chamber 25B from the target pressure TP2 to the pressure LP2 is started at the same time as or after the operation of increasing the pressure in the pressure chamber 25C from the pressure IP3 to the target pressure TP3 is started.

A point in time at which the pressurization of the pressure chamber 25D is started is a point in time T7 in FIG. 21. After the pressure in the pressure chamber 25D reaches a pressure IP4 at a point in time T8 shown in FIG. 21, the pressure controlling system 60 maintains the pressure IP4 in the pressure chamber 25D (see FIG. 21). The operation of increasing the pressure in the pressure chamber 25C from the pressure IP3 to the target pressure TP3 is started at the same time as the pressurization of the pressure chamber 25D is started. Specifically, the pressure controlling system 60 starts increasing the pressure in the pressure chamber 25C and starts pressurizing the pressure chamber 25D at the point in time T7. In one embodiment, the operation of increasing the pressure in the pressure chamber 25C from the pressure IP3 to the target pressure TP3 may be started before the pressurization of the pressure chamber 25D is started. Specifically, the pressure controlling system 60 may start increasing the pressure in the pressure chamber 25C at a point in time before the point in time T7 at which the pressurization of the pressure chamber 25D is started.

Next, as shown in FIG. 20, the pressure controlling system 60 operates the pressure regulator Ra3 to lower the pressure in the pressure chamber 25C from the target pressure TP3 to a preset pressure LP3. In one example, the pressure LP3 may be the same as the pressure (initial pressure) IP3, or may be different from the pressure (initial pressure) IP3. After the pressure in the pressure chamber 25C has been lowered to the pressure LP3, the pressure controlling system 60 maintains the pressure LP3 in the pressure chamber 25C. The fluid Q has already been removed from the upper surface of the wafer W, so that the fluid Q does not flow backward even if the pressure in the pressure chamber 25C is lowered.

According to this embodiment, the pressure in the pressure chamber 25C is reduced, so that the polishing rate of the region of the wafer W corresponding to the pressure chamber 25C can be prevented from locally increasing before polishing of the wafer W is started.

The operation of lowering the pressure in the pressure chamber 25C from the target pressure TP3 to the pressure LP3 is started after the pressure in the pressure chamber 25D is increased from the pressure IP4 to the target pressure TP4.

With the operations shown in FIGS. 16 to 20, the fluid Q present between the upper surface of the wafer W and the elastic membrane 34 of the polishing head 1 is pushed outward by the elastic membrane 34 and is discharged from the wafer W. The pressure controlling system 60 then forms polishing pressures required to polish the wafer W in the pressure chambers 25A to 25D, so that the polishing head 1 can press the lower surface of the wafer W against the polishing surface 2a of the polishing pad 2 with the elastic membrane 34 to polish the lower surface of the wafer W. The polishing head 1 can apply intended pressures to the regions of the wafer W corresponding to the pressure chambers 25A to 25D.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method for a workpiece using a polishing head having a plurality of pressure chambers formed by an elastic membrane, comprising:
pressurizing a first pressure chamber to move fluid present between an upper surface of the workpiece and the first pressure chamber outward, the plurality of pressure chambers including the first pressure chamber;
moving the fluid present between the upper surface of the workpiece and a second pressure chamber outward by pressurizing the second pressure chamber to form a second pressure in the second pressure chamber when a first pressure is formed in the first pressure chamber, the first pressure being equal to or higher than a first target pressure, the second pressure being lower than the first target pressure, the plurality of pressure chambers including the second pressure chamber located outwardly of the first pressure chamber; and
pressing a lower surface of the workpiece against a polishing surface with the elastic membrane to polish the lower surface of the workpiece after causing the fluid to flow out from the upper surface of the workpiece.

2. The polishing method according to claim 1, wherein pressurizing the first pressure chamber comprises pressurizing the first pressure chamber to form a first initial pressure in the first pressure chamber which is lower than the first target pressure, and
pressure in the first pressure chamber is increased from the first initial pressure to the first target pressure after the first initial pressure is formed in the first pressure chamber.

3. The polishing method according to claim 2, wherein the operation of increasing the pressure in the first pressure chamber from the first initial pressure to the first target pressure is started at the same time as or before the pressurization of the second pressure chamber is started.

4. The polishing method according to claim 1, wherein
pressurizing the first pressure chamber comprises pressurizing the first pressure chamber to form the first target pressure in the first pressure chamber, and
pressurizing the second pressure chamber to form the second pressure in the second pressure chamber which is lower than the first target pressure comprises pressurizing the second pressure chamber to form a second target pressure in the second pressure chamber when the first pressure equal to or higher than the first target pressure is formed in the first pressure chamber, the second target pressure being lower than the first target pressure.

5. The polishing method according to claim 2, wherein
the plurality of pressure chambers further include a third pressure chamber located outwardly of the second pressure chamber,
the second pressure in the second pressure chamber which is lower than the first target pressure comprises a second initial pressure lower than the first target pressure, and
the polishing method further comprises:
lowering pressure in the first pressure chamber from the first target pressure while increasing pressure in the second pressure chamber from the second initial pressure to a second target pressure; and
moving the fluid present between the upper surface of the workpiece and the third pressure chamber outward by pressurizing the third pressure chamber to form a third pressure in the third pressure chamber when the second target pressure is formed in the second pressure chamber, the third pressure being lower than the second target pressure.

6. A polishing apparatus for a workpiece, comprising:
a polishing table configured to support a polishing pad having a polishing surface;
a polishing head having a plurality of pressure chambers formed by an elastic membrane, the polishing head being configured to press the workpiece against the polishing surface with the elastic membrane; and
a pressure controlling system configured to control pressures in the plurality of pressure chambers,
wherein the plurality of pressure chambers include a first pressure chamber, and a second pressure chamber located outwardly of the first pressure chamber,
the pressure controlling system is configured to:
pressurize the first pressure chamber to move fluid present between an upper surface of the workpiece and the first pressure chamber outward;
move the fluid present between the upper surface of the workpiece and the second pressure chamber outward by pressurizing the second pressure chamber to form a second pressure in the second pressure chamber when a first pressure is formed in the first pressure chamber, the first pressure being equal to or higher than a first target pressure, the second pressure being lower than the first target pressure; and
pressurize the plurality of pressure chambers to press a lower surface of the workpiece against the polishing surface with the elastic membrane to polish the lower surface of the workpiece after the fluid is caused to flow out from the upper surface of the workpiece.

7. The polishing apparatus according to claim 6, wherein
the pressure controlling system is configured to:
pressurize the first pressure chamber to form a first initial pressure in the first pressure chamber which is lower than the first target pressure; and
increase pressure in the first pressure chamber from the first initial pressure to the first target pressure.

8. The polishing apparatus according to claim 7, wherein the pressure controlling system is configured to start the operation of increasing the pressure in the first pressure chamber from the first initial pressure to the first target pressure at the same time as or before the pressurization of the second pressure chamber is started.

9. The polishing apparatus according to claim 6, wherein
the pressure controlling system is configured to:
pressurize the first pressure chamber to form the first target pressure in the first pressure chamber; and
pressurize the second pressure chamber to form a second target pressure in the second pressure chamber when the first pressure equal to or higher than the first target pressure is formed in the first pressure chamber, the second target pressure being lower than the first target pressure.

10. The polishing apparatus according to claim 7, wherein
the plurality of pressure chambers further include a third pressure chamber located outwardly of the second pressure chamber,
the second pressure in the second pressure chamber which is lower than the first target pressure comprises a second initial pressure lower than the first target pressure, and
the pressure controlling system is configured to:
lower pressure in the first pressure chamber from the first target pressure while increasing pressure in the second pressure chamber from the second initial pressure to a second target pressure; and
move the fluid present between the upper surface of the workpiece and the third pressure chamber outward by pressurizing the third pressure chamber to form a third pressure in the third pressure chamber when the second target pressure is formed in the second pressure chamber, the third pressure being lower than the second target pressure.
